(19) United States
(12) Patent Application Publication
(10) Pub. No.: US 2024/0179843 A1
(43) Pub. Date: May 30, 2024

(54) ELECTRONIC CIRCUIT BOARD AND ELECTRONIC DEVICE

(71) Applicant: Sony Group Corporation, Tokyo (JP)

(72) Inventors: Yoshihiro KATO, Tokyo (JP); Hiroshi KATAYAMA, Tokyo (JP); Hiroki NAKAIE, Tokyo (JP); Toshihiro KOGA, Tokyo (JP)

(73) Assignee: Sony Group Corporation, Tokyo (JP)

(21) Appl. No.: 18/551,598

(22) PCT Filed: Mar. 29, 2021
(86) PCT No.: PCT/JP2021/013426

§ 371 Date: Sep. 21, 2023

(51) Int. Cl. H05K 1/14; H05K 1/02; H05K 1/18

(52) U.S. Cl. CPC H05K 1/144; H05K 1/181; H05K 1/0221; H05K 2201/10378; H05K 2201/2009

(57) ABSTRACT

An electronic circuit board includes first and second circuit boards, and a relay board sandwiched between the first and second circuit boards and electrically connecting the first and second circuit boards to each other. Reinforcement between the first circuit board and the relay board is made by using an electronic component for reinforcement provided at an internal corner portion between the first circuit board and the relay board among electronic components mounted on the first circuit board.

### FIELD

The present disclosure relates to an electronic circuit board and an electronic device.

### BACKGROUND

In an electronic device, such as a smartphone or a camera, an electronic circuit board on which various electronic components are mounted is housed in an exterior casing constituting an exterior (see Patent Literature 1, for example).

### CITATION LIST

### Patent Literature

Patent Literature 1: JP 2019-29371 A

### SUMMARY

### Technical Problem

When the number of electronic components mounted on the electronic circuit board increases with the improvement in the performance of the electronic device, the board area of the electronic circuit board may be increased to secure a mounting space for the electronic components. When the board area of the electronic circuit board is increased in this way, the area occupied by the electronic circuit board in the exterior casing may increase, leading to an increase in size.

The present disclosure proposes an electronic circuit board and an electronic device that can be downsized.

### Solution to Problem

According to the present disclosure, an

electronic circuit board is provided that includes: a first circuit board; a second circuit board; and a relay board sandwiched between the first circuit board and the second circuit board and electrically connecting the first circuit board and the second circuit board to each other, wherein reinforcement between at least one of the first circuit board and the second circuit board and the relay board is made by using an electronic component for reinforcement provided at an internal corner portion between the at least one circuit board and the relay board among electronic components mounted on the at least one circuit board.

Moreover, according to the present disclosure, an electronic device is provided that includes: an exterior casing constituting an exterior; an electronic circuit board housed in the exterior casing, wherein the electronic circuit board includes: a first circuit board; a second circuit board; and a relay board sandwiched between the first circuit board and the second circuit board and electrically connecting the first circuit board and the second circuit board to each other, reinforcement between at least one of the first circuit board and the second circuit board and the relay board is made by using an electronic component for reinforcement provided at an internal corner portion between the at least one circuit board and the relay board among electronic components mounted on the at least one circuit board.

### BRIEF DESCRIPTION OF DRAWINGS

FIG. 1 is a diagram illustrating an electronic device according to a first embodiment of the present disclosure.

FIG. 2 is a diagram illustrating a configuration of an electronic circuit board.

FIG. 3 is a diagram illustrating a configuration of an electronic circuit board.

FIG. 4 is a diagram for explaining an effect of the first embodiment.

FIG. 5 is a diagram for explaining an effect of the first embodiment.

FIG. 6 is a diagram illustrating Modification 1-1 of the first embodiment.

FIG. 7 is a diagram illustrating a reinforcement structure between first and second circuit boards and a relay board according to a second embodiment of the present disclosure.

FIG. 8 is a diagram illustrating Modification 2-1 of the second embodiment.

FIG. 9 is a diagram illustrating Modification 2-2 of the second embodiment.

FIG. 10 is a diagram illustrating Modification 2-3 of the second embodiment.

FIG. 11 is a diagram illustrating Modification 2-4 of the second embodiment.

FIG. 12 is a diagram illustrating Modification 2-5 of the second embodiment.

FIG. 13 is a diagram illustrating a structure of a transmission line in a relay board according to a third embodiment of the present disclosure.

FIG. 14 is a diagram for explaining an effect of the third embodiment.

FIG. 15 is a diagram illustrating Modification 3-1 of the third embodiment.

### DESCRIPTION OF EMBODIMENTS

Hereinafter, embodiments of the present disclosure will be described with reference to the drawings. The present disclosure is not limited by the embodiments described below. In the description of the drawings, the same portions are denoted by the same reference numerals.

### First Embodiment

### Schematic Configuration of Electronic Device

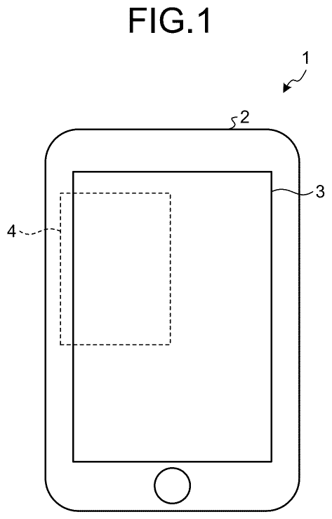

FIG. 1 is a diagram illustrating an electronic device 1 according to a first embodiment of the present disclosure.

In the first embodiment, the electronic device 1 is a smartphone as illustrated in FIG. 1. The electronic device 1 includes an exterior casing 2 constituting an exterior, a display unit 3 exposed outside the exterior casing 2 to display a predetermined image, and an electronic circuit board 4.

The electronic circuit board 4 is an electronic circuit board including a plurality of electronic components, such as a communication interface for performing communication by a communication method using a wireless local area network (LAN) such as Wi-Fi (registered trademark) or a communication method using a mobile phone line such as 4G or 5G, a central processing unit (CPU) that controls the entire operation of the electronic device 1, and a memory.

Hereinafter, a detailed configuration of the electronic circuit board 4 will be described.

### Configuration of Electronic Circuit Board

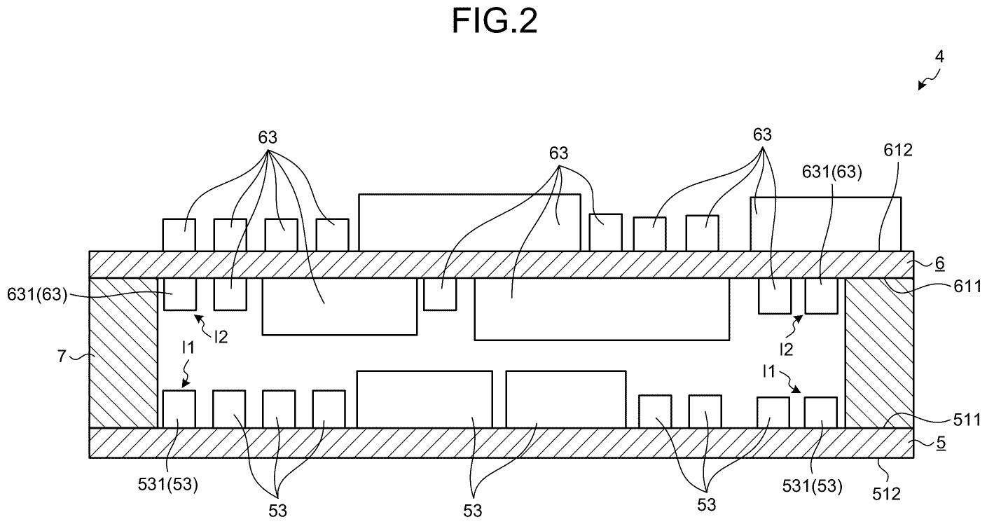

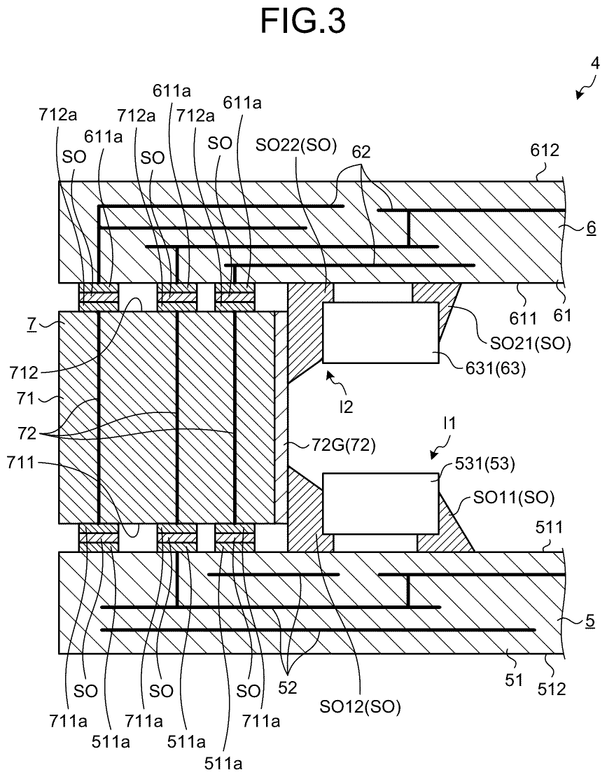

FIGS. 2 and 3 are diagrams illustrating a configuration of the electronic circuit board 4. Specifically, FIG. 2 is a sectional view of the electronic circuit board 4 taken along a plane orthogonal to the paper surface of FIG. 1. FIG. 3 is an enlarged view of a part of FIG. 2.

As illustrated in FIG. 2 or 3, the electronic circuit board 4 includes a first circuit board 5, a second circuit board 6, and a relay board 7. The electronic circuit board 4 has a stack structure in which the relay board 7 is sandwiched between the first and second circuit boards 5 and 6.

As illustrated in FIG. 2 or 3, the first circuit board 5 includes a first board part 51 (FIG. 3), a first transmission line 52 (FIG. 3), and a plurality of first electronic components 53.

The first board part 51 is formed of an insulator and has a flat plate shape. For example, the first board part 51 is a resin multilayer board or a ceramic multilayer board obtained by stacking resin sheets.

In the first board part 51, as illustrated in FIG. 3, a plurality of (only three are illustrated in FIG. 3) first pads 511a electrically connected to the first transmission line 52 are provided on a plate surface 511 (upper plate surface in FIGS. 2 and 3), the plate surface facing the second circuit board 6.

The first transmission line 52 is a signal line serving as a signal line or a power supply line, or a ground line to form ground connection, and is provided on the surface of the first board part 51 or inside the first board part 51.

The plurality of first electronic components 53 are electronic components such as the communication interface, the CPU, and the memory described above. The plurality of first electronic components 53 are mounted on the first board part 51 in a state of being electrically connected to the first transmission line 52 by solder SO (FIG. 3). In FIG. 2 or 3, the plurality of first electronic components 53 are provided only on the plate surface 511, but they may also be provided on a plate surface 512 that makes the two sides with the plate surface 511.

Hereinafter, for convenience of description, among the plurality of the first electronic components 53, an electronic component 53 provided at an internal corner portion I1 (FIGS. 2 and 3) between the first circuit board 5 and the relay board 7 will be referred to as a first electronic component for reinforcement 531 (FIGS. 2 and 3).

The first electronic component for reinforcement 531 is also used for reinforcement between the first circuit board 5 and the relay board 7. The reinforcement structure between the first circuit board 5 and the relay board 7 will be described in “Reinforcement Structure Between First and Second Circuit Boards and Relay Board” described later.

As illustrated in FIG. 2 or 3, the second circuit board 6 includes a second board part 61 (FIG. 3), a second transmission line 62 (FIG. 3), and a plurality of second electronic components 63.

The second board part 61 is formed of an insulator and has a flat plate shape. For example, the second board part 61 is a resin multilayer board or a ceramic multilayer board obtained by stacking resin sheets.

In the second board part 61, as illustrated in FIG. 3, a plurality of (only three are illustrated in FIG. 3) second pads 611a electrically connected to the second transmission line 62 are provided on a plate surface 611 (lower plate surface in FIGS. 2 and 3), the plate surface facing the first circuit board 5.

The second transmission line 62 is a signal line serving as a signal line or a power supply line, or a ground line to form ground connection, and is provided on the surface of the second board part 61 or inside the second board part 61.

The plurality of second electronic components 63 are electronic components such as the communication interface, the CPU, and the memory described above. The plurality of second electronic components 63 are mounted on the second board part 61 in a state of being electrically connected to the second transmission line 62 by solder SO (FIG. 3). In FIG. 2 or 3, the plurality of second electronic components 53 are provided on both the plate surface 611 and a plate surface 612 that makes the two sides with the plate surface 611, but they may be provided only on one plate surface of the plate surfaces 611 and 612.

Hereinafter, for convenience of description, among the plurality of the second electronic components 63, an electronic component 63 provided at an internal corner portion I2 (FIGS. 2 and 3) between the second circuit board 6 and the relay board 7 will be referred to as a second electronic component for reinforcement 631 (FIGS. 2 and 3).

The second electronic component for reinforcement 631 is also used for reinforcement between the second circuit board 6 and the relay board 7. The reinforcement structure between the second circuit board 6 and the relay board 7 will be described in “Reinforcement Structure Between First and Second Circuit Boards and Relay Board” described later.

The relay board 7 is a board that electrically connects the first and second transmission lines 52 and 62 (signal lines and ground lines) in the first and second circuit boards 5 and 6 to each other. The relay board 7 may also be referred to as an interposer board, a frame interposer, a spacer board, or a connector board. As illustrated in FIG. 3, the relay board 7 includes a board part 71 and a transmission line 72.

The board part 71 is formed of an insulator and has a frame shape. In the first embodiment, the board part 71 is formed of a single-layer board, but it may be formed of, for example, a resin multilayer board or a ceramic multilayer board obtained by stacking resin sheets. The board part 71 does not have to have a frame shape as long as it has a prism shape extending from the first circuit board 5 side toward the second circuit board 6 side.

In the board part 71, as illustrated in FIG. 3, a plurality of (only three are illustrated in FIG. 3) first lands 711a electrically connected to the transmission line 72 are provided on a surface 711 (upper surface in FIGS. 2 and 3), the surface facing the first circuit board 5.

In the board part 71, as illustrated in FIG. 3, a plurality of (only three are illustrated in FIG. 3) second lands 712a electrically connected to the transmission line 72 are provided on a surface 712 (lower surface in FIGS. 2 and 3), the surface facing the second circuit board 6.

As illustrated in FIG. 3, the relay board 7 is fixed to the first circuit board 5 by connecting the plurality of the first lands 711a to the plurality of the first pads 511a by solder SO, respectively. The relay board 7 is fixed to the second circuit board 6 by connecting the plurality of the second lands 712a to the plurality of the second pads 611a by solder SO, respectively. This causes the first and second transmission lines 52 and 62 (signal lines and ground lines) to be electrically connected to each other via the transmission line 72.

The transmission line 72 is a signal line serving as a signal line or a power supply line, or a ground line to form ground connection, and is provided on a side surface of the board part 71 or inside the board part 71. In the first embodiment, a ground line 72G (transmission line 72) is provided on a side surface of the board part 71. Although not specifically illustrated, the ground line 72G electrically connects the ground lines in the first and second circuit boards 5 and 6 to each other.

### Reinforcement Structure Between First and Second Circuit Boards and Relay Board

Next, a reinforcement structure between the first and second circuit boards 5 and 6 and the relay board 7 will be described.

First, a reinforcement structure between the first circuit board 5 and the relay board 7 using the first electronic component for reinforcement 531 will be described.

In the first embodiment, the first electronic component for reinforcement 531 is formed of a bypass capacitor. The first electronic component for reinforcement 531 is provided with a power supply terminal (not illustrated) electrically connected to the first transmission line 51 (signal line) in the first circuit board 5 by solder SO (solder SO11 (FIG. 3)). The first electronic component for reinforcement 531 is provided with a ground terminal (not illustrated) electrically connected to the ground line 72G in the relay board 7 by solder SO (solder SO12 (FIG. 3)). In the first embodiment, the solder SO12 is also connected to the plate surface 511 of the first circuit board 5.

Connecting the first electronic component for reinforcement 531 as described above causes the solders SO11 and SO12 and the first electronic component for reinforcement 531 to function as “angle braces” in architecture at the internal corner portion I1 and reinforce the connection state between the first circuit board 5 and the relay board 7.

Only one first electronic component for reinforcement 531 may be provided, or a plurality of first electronic components for reinforcement 531 may be provided along a direction orthogonal to the paper surface of FIG. 3.

Next, a reinforcement structure between the second circuit board 6 and the relay board 7 using the second electronic component for reinforcement 631 will be described.

In the first embodiment, the second electronic component for reinforcement 631 is formed of a bypass capacitor. The second electronic component for reinforcement 631 is provided with a power supply terminal (not illustrated) electrically connected to the second transmission line 61 (signal line) in the second circuit board 6 by solder SO (solder SO21 (FIG. 3)). The second electronic component for reinforcement 631 is provided with a ground terminal (not illustrated) electrically connected to the ground line 72G in the relay board 7 by solder SO (solder SO22 (FIG. 3)). In the first embodiment, the solder SO22 is also connected to the plate surface 611 of the second circuit board 6.

Connecting the second electronic component for reinforcement 631 as described above causes the solders SO21 and SO22 and the second electronic component for reinforcement 631 to function as “angle braces” in architecture at the internal corner portion I2 and reinforce the connection state between the second circuit board 6 and the relay board 7.

Only one first electronic component for reinforcement 531 may be provided, or a plurality of first electronic components for reinforcement 531 may be provided along a direction orthogonal to the paper surface of FIG. 3.

### Effect of First Embodiment

The first embodiment described above has the following effect.

The electronic circuit board 4 according to the first embodiment has a stack structure in which the relay board 7 is sandwiched between the first and second circuit boards 5 and 6.

That is, the first and second circuit boards 5 and 6 are stacked in a direction orthogonal to the paper surface in FIG. 1 with the stack structure. Thus, even when the number of electronic components mounted on the electronic circuit board 4 is increased with the improvement in performance of the electronic device 1, the area occupied by the electronic circuit board 4 in the planar direction (In FIG. 1, a direction parallel to the paper surface) in the exterior casing 2 does not increase.

Therefore, the electronic circuit board 4 according to the first embodiment can be downsized.

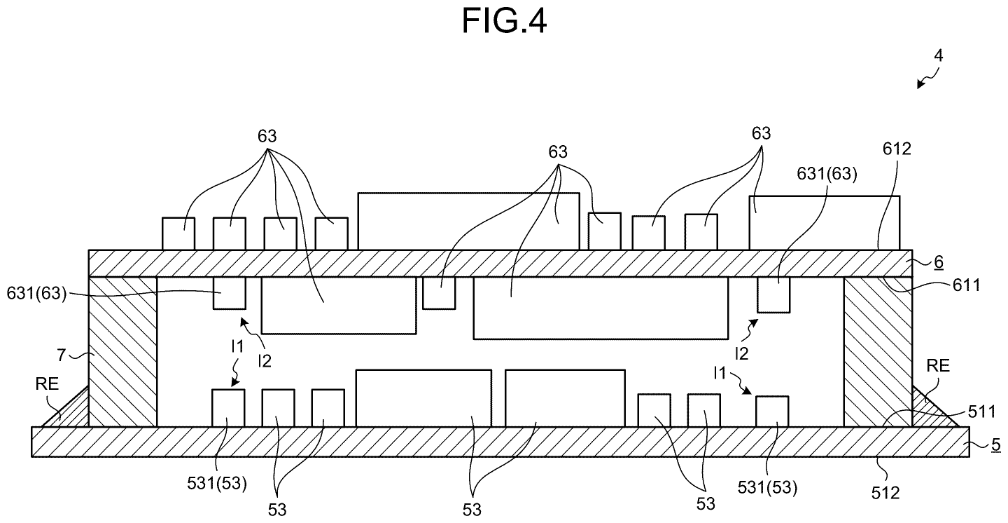

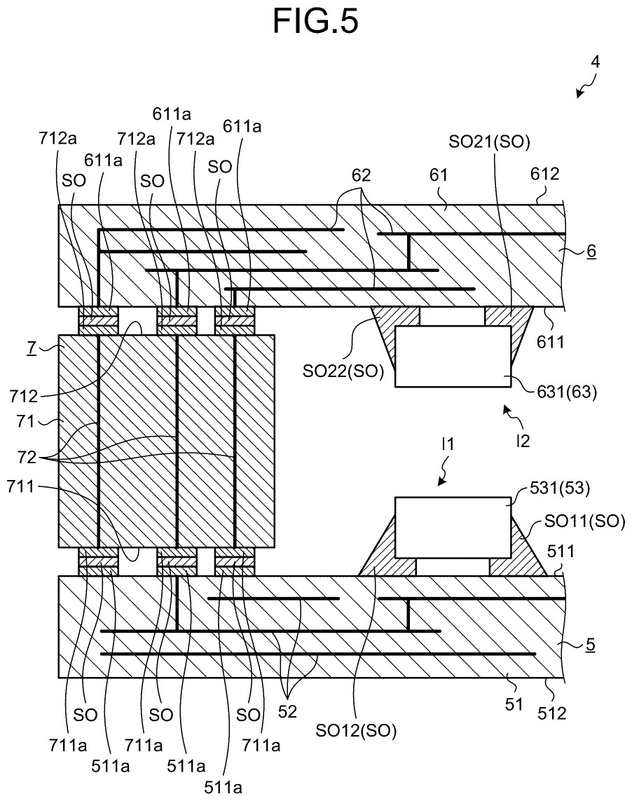

FIGS. 4 and 5 are diagrams for explaining the effect of the first embodiment. Specifically, FIG. 4 is a diagram for explaining a problem in a case where the electronic circuit board 4 has the stack structure, corresponding to FIG. 2. FIG. 5 is an enlarged view of a part of FIG. 4.

In downsizing the electronic circuit board 4 having the stack structure, the connection strength between the first and second circuit boards 5 and 6 and the relay board 7 needs to be sufficiently secured. As a structure capable of sufficiently securing the connection strength, the following first and second structures may be considered.

The first structure is a structure in which a connection area between the first and second circuit boards 5 and 6 and the relay board 7 by the solder so is increased.

However, when the first structure is employed, the area of the electronic circuit board 4 in the planar direction (In FIG. 1, a direction parallel to the paper surface) increases by the amount corresponding to an increase in the connection area with the solder SO, which disturbs the downsizing.

The second structure is a structure in which a resin RE is filled in an internal corner portion between the first circuit board 5 and the relay board 7 as illustrated in FIG. 4, for example.

However, when the second structure is employed, a post-process of filling the resin RE is increased after the first and second circuit boards 5 and 6 are connected to the relay board 7 with the solder SO. In addition, it is necessary to secure a board area for filling the resin RE, which disturbs the downsizing.

In contrast, in the first embodiment, the first and second electronic components for reinforcement 531 and 631 are used as the reinforcement structures between the first and second circuit boards 5 and 6 and the relay board 7.

That is, the solders SO11 and SO12 and the first electronic component for reinforcement 531 function as “angle braces” in architecture at the internal corner portion I1. In the same manner, the solders SO21 and SO22 and the second electronic component for reinforcement 631 function as “angle braces” in architecture at the internal corner portion I2.

Thus, employing the reinforcement structures using the first and second electronic components for reinforcement 531 and 631 enables sufficient reinforcement of the connection state between the first and second circuit boards 5 and 6 and the relay board 7 without causing the problems in the above-described first and second structures.

In particular, the solder SO12 is also connected to the plate surface 511 of the first circuit board 5. That is, even the solder SO12 alone functions as an “angle brace” in architecture at the internal corner portion I1. In the same manner, the solder SO22 is also connected to the plate surface 611 of the second circuit board 6. That is, even the solder SO22 alone functions as an “angle brace” in architecture at the internal corner portion I2. Thus, the connection state between the first and second circuit boards 5 and 6 and the relay board 7 can be further reinforced.

In addition, using the first and second electronic components for reinforcement 531 and 631 as the reinforcement structures between the first and second circuit boards 5 and 6 and the relay board 7 can shorten the separation distance between the relay board 7 and the first and second electronic components for reinforcement 531 and 631 (see FIGS. 3 and 5). Therefore, as the separation distance is shortened, the board area can be reduced, and further downsizing can be achieved.

### Modification 1-1 of First Embodiment

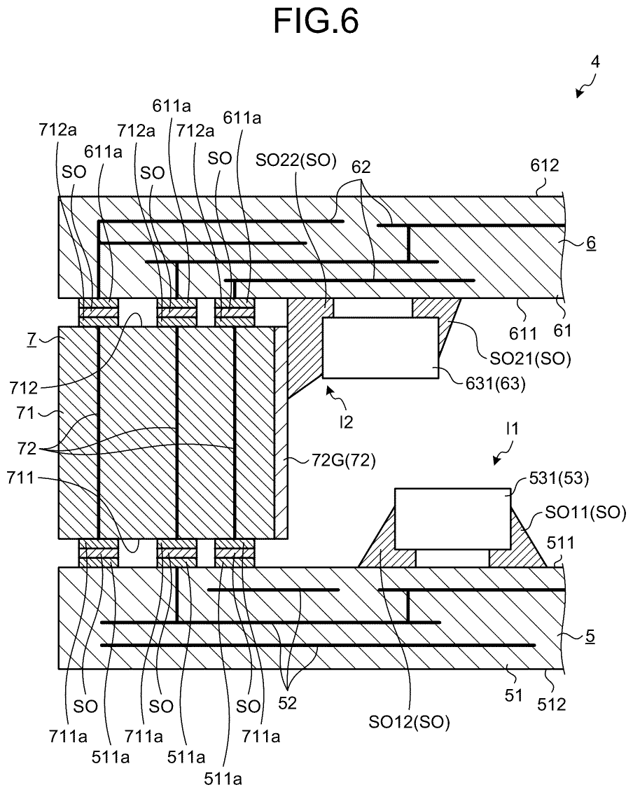

FIG. 6 is a diagram illustrating Modification 1-1 of the first embodiment. Specifically, FIG. 6 is a diagram corresponding to FIG. 3.

In the first embodiment described above, reinforcement is made between the first circuit board 5 and the relay board 7 and between the second circuit board 6 and the relay board 7, but the reinforcement is not limited to this configuration.

The reinforcement may be made only between the first circuit board 5 and the relay board 7 or only between the second circuit board 6 and the relay board 7. In Modification 1-1 illustrated in FIG. 6, a structure is illustrated in which reinforcement with the second electronic component for reinforcement 631 is made only between the second circuit board 6 and the relay board 7.

### Second Embodiment

Next, a second embodiment will be described.

Hereinafter, the same reference numerals are given to the same configurations as those of the above-described first embodiment, and the detailed description thereof will be omitted or simplified.

In the electronic circuit board 4 according to the second embodiment, as the reinforcement structures between the first and second circuit boards 5 and 6 and the relay board 7, the reinforcement structures using the first and second electronic components for reinforcement 531 and 631 are employed as in the first embodiment described above, and another reinforcement structure is also added.

### Reinforcement Structure Between First and Second Circuit Boards and Relay Board

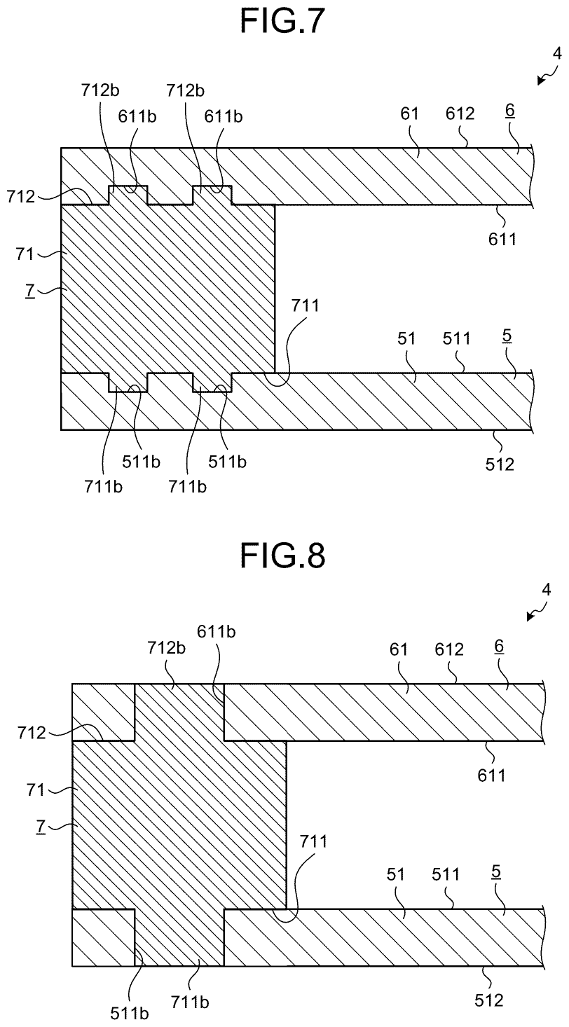

FIG. 7 is a diagram illustrating a reinforcement structure between the first and second circuit boards 5 and 6 and the relay board 7 according to the second embodiment of the present disclosure. Specifically, FIG. 7 is a diagram corresponding to FIG. 3. In FIG. 7, for convenience of explanation, illustration of the first and second pads 511a and 611a, the first and second transmission lines 52 and 62, the first and second electronic components for reinforcement 531 and 631, the solder SO, the first and second lands 711a and 712a, and the transmission line 72 is omitted.

First, a reinforcement structure between the first circuit board 5 and the relay board 7 will be described.

As illustrated in FIG. 7, the surface 711 of the board part 71 is provided with a plurality of (only two are illustrated in FIG. 7) protrusions 711b protruding toward the first circuit board 5.

On the other hand, the plate surface 511 of the first board part 51 is provided with a plurality of first fitting receiving portions 511b which are recessed toward the other plate surface 512 side and into which the plurality of protrusion 711b may be fitted respectively.

Reinforcement between the first circuit board 5 and the relay board 7 is made by the plurality of protrusions 711b respectively fitted into the plurality of first fitting receiving portions 511b.

The protrusions 711b are integrally formed with the relay board 7, protrude from the relay board 7 toward the first circuit board 5, and are inserted into the first circuit board 5, and thus they correspond to reinforcement members according to the present disclosure.

Next, a reinforcement structure between the second circuit board 6 and the relay board 7 will be described.

As illustrated in FIG. 7, the surface 712 of the board part 71 is provided with a plurality of (only two are illustrated in FIG. 7) protrusions 712b protruding toward the second circuit board 6.

On the other hand, the plate surface 611 of the second board part 61 is provided with a plurality of second fitting receiving portions 611b which are recessed toward the other plate surface 612 side and into which the plurality of protrusion 712b may be fitted respectively.

Reinforcement between the second circuit board 6 and the relay board 7 is made by the plurality of protrusions 712b respectively fitted into the plurality of second fitting receiving portions 611b.

The protrusions 712b are integrally formed with the relay board 7, protrude from the relay board 7 toward the second circuit board 6, and are inserted into the second circuit board 6, and thus they correspond to reinforcement members according to the present disclosure.

### Effect of Second Embodiment

The second embodiment, in which the protrusions 711b and 712b and the first fitting receiving portions 511b and 611b are used, can reinforce between the first and second circuit boards 5 and 6 and the relay board 7 with a simple structure.

In the second embodiment described above, reinforcement is made between the first circuit board 5 and the relay board 7 and between the second circuit board 6 and the relay board 7, but the reinforcement is not limited to this configuration.

One of the pair of the protrusion 711b and the first fitting receiving portion 511b and the pair of the protrusion 712b and the second fitting receiving portion 611b may be omitted. That is, the reinforcement may be made only between the first circuit board 5 and the relay board 7 or only between the second circuit board 6 and the relay board 7.

### Modification 2-1 of Second Embodiment

FIG. 8 is a diagram illustrating Modification 2-1 of the second embodiment. Specifically, FIG. 8 is a diagram corresponding to FIG. 7.

In the second embodiment described above, the first fitting receiving portions 511b and 611b may be changed to the structure of Modification 2-1 illustrated in FIG. 8. That is, the first fitting receiving portion 511b according to Modification 2-1 illustrated in FIG. 8 is formed of a through hole penetrating between the plate surfaces 511 and 512. The second fitting receiving portion 611b according to Modification 2-1 illustrated in FIG. 8 is formed of a through hole penetrating between the plate surfaces 611 and 612.

In the second embodiment described above, the number of the protrusions 711b is not limited to two, and other numbers may be employed. The same applies to the number of protrusions 721b. In Modification 2-1 illustrated in FIG. 8, one protrusion 711b and one protrusion 712b are provided.

### Modification 2-2 of Second Embodiment

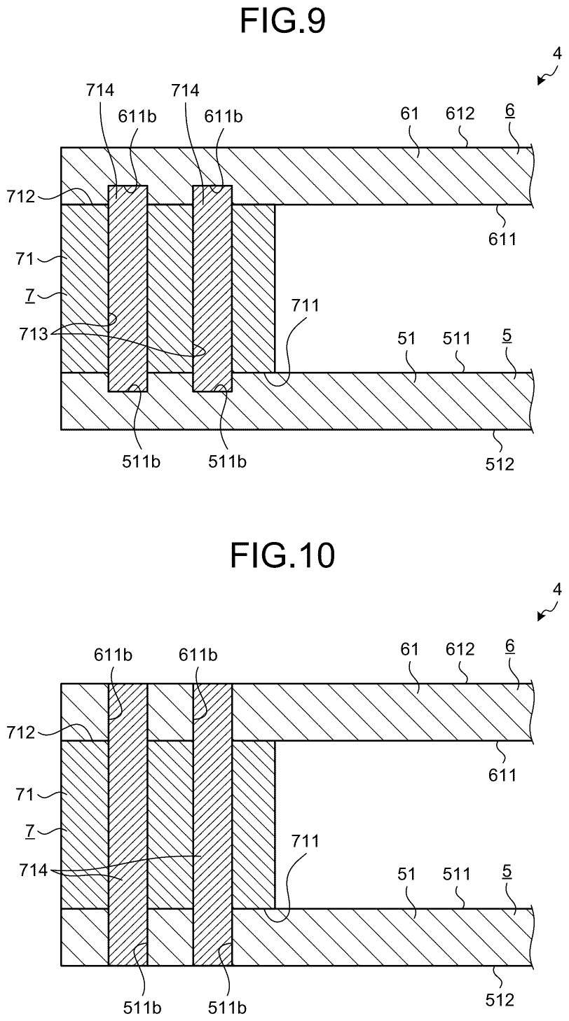

FIG. 9 is a diagram illustrating Modification 2-2 of the second embodiment. Specifically, FIG. 9 is a diagram corresponding to FIG. 7.

In the second embodiment described above, the reinforcement member according to the present disclosure is integrally formed with the board part 71, but the reinforcement member is not limited to this configuration. As the reinforcement member according to the present disclosure, a plurality of (only two are illustrated in FIG. 9) reinforcement members 714 formed separately from the board part 71 may be employed as in Modification 2-2 illustrated in FIG. 9. The reinforcement member 714 is an elongated member, and an end thereof may be fitted to the first fitting receiving portions 511b and 611b.

As illustrated in FIG. 9, the board part 71 is provided with a plurality of (two in the example of FIG. 9) through holes 713 penetrating between the surfaces 711 and 712. The reinforcement member 714 is fitted into the through hole 713 in a state where both ends protrude outside the through hole 713.

Reinforcement between the first circuit board 5 and the relay board 7 is made by one ends of the plurality of reinforcement members 714 respectively fitted into the plurality of first fitting receiving portions 511b.

Reinforcement between the second circuit board 6 and the relay board 7 is made by the other ends of the plurality of reinforcement members 714 respectively fitted into the plurality of second fitting receiving portions 611b.

### Modification 2-3 of Second Embodiment

FIG. 10 is a diagram illustrating Modification 2-3 of the second embodiment. Specifically, FIG. 10 is a diagram corresponding to FIG. 7.

In Modification 2-2 described above, the first fitting receiving portions 511b and 611b may be changed to the structure of Modification 2-3 illustrated in FIG. 10. That is, the first fitting receiving portion 511b according to Modification 2-3 illustrated in FIG. 10 is formed of a through hole penetrating between the plate surfaces 511 and 512. In the same manner, the second fitting receiving portion 611b according to Modification 2-3 illustrated in FIG. 10 is formed of a through hole penetrating between the plate surfaces 611 and 612.

### Modification 2-4 of Second Embodiment

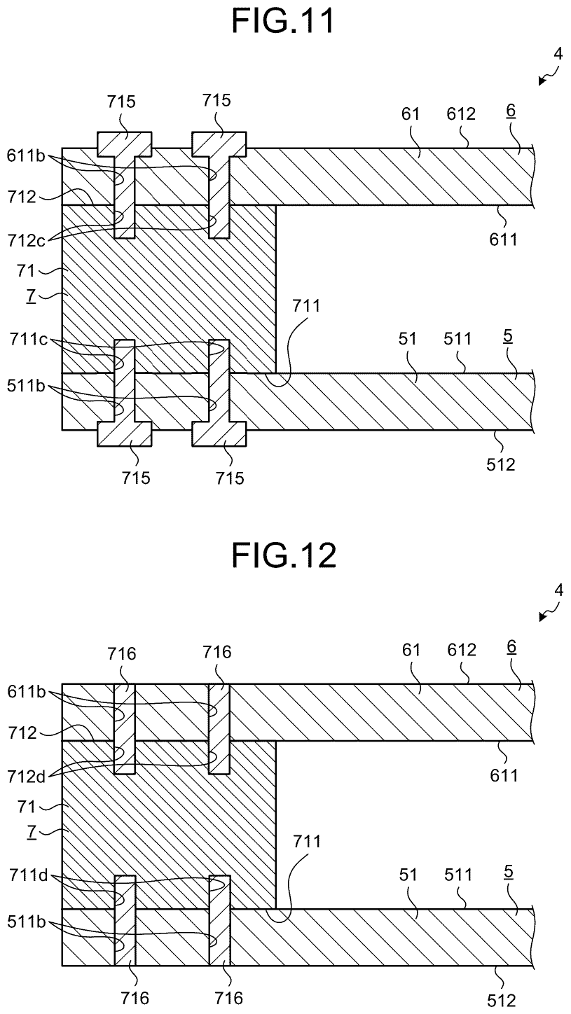

FIG. 11 is a diagram illustrating Modification 2-4 of the second embodiment. Specifically, FIG. 11 is a diagram corresponding to FIG. 7.

In the second embodiment described above, the reinforcement member according to the present disclosure is integrally formed with the board part 71, but the reinforcement member is not limited to this configuration. As the reinforcement member according to the present disclosure, a plurality of (only four are illustrated in FIG. 11) reinforcement members 715 formed separately from the board part 71 may be employed as in Modification 2-4 illustrated in FIG. 11. The reinforcement member 715 is a screw.

The first fitting receiving portion 511b according to Modification 2-4 is formed of a through hole penetrating between the plate surfaces 511 and 512 and allowing the reinforcement member 715 to be inserted therethrough.

Further, in the board part 71, the surface 711 is provided with a plurality of (only two are illustrated in FIG. 11) first screw holes 711c which are recessed toward the surface 712 and into which the reinforcement member 715 may be screwed.

Reinforcement between the first circuit board 5 and the relay board 7 is made by the reinforcement member 715 inserted into the first fitting receiving portion 511b and screwed into the first screw hole 711c.

The second fitting receiving portion 611b according to Modification 2-4 is formed of a through hole penetrating between the plate surfaces 611 and 612 and allowing the reinforcement member 715 to be inserted therethrough.

Further, in the board part 71, the surface 712 is provided with a plurality of (only two are illustrated in FIG. 11) second screw holes 712c which are recessed toward the surface 711 and into which the reinforcement member 715 may be screwed.

Reinforcement between the second circuit board 6 and the relay board 7 is made by the reinforcement member 715 inserted into the second fitting receiving portion 611b and screwed into the second screw hole 712c.

The first and second fitting receiving portions 511b and 611b and the first and second screw holes 711c and 712c are not limited to the configuration in which they are provided in advance. They may be formed in the process of inserting the reinforcement member 715.

### Modification 2-5 of Second Embodiment

FIG. 12 is a diagram illustrating Modification 2-5 of the second embodiment. Specifically, FIG. 12 is a diagram corresponding to FIG. 7.

In the second embodiment described above, the reinforcement member according to the present disclosure is integrally formed with the board part 71, but the reinforcement member is not limited to this configuration. As the reinforcement member according to the present disclosure, a plurality of (only four are illustrated in FIG. 12) reinforcement members 716 formed separately from the board part 71 may be employed as in Modification 2-5 illustrated in FIG. 12. The reinforcement member 716 is a pin.

The first fitting receiving portion 511b according to Modification 2-5 is formed of a through hole penetrating between the plate surfaces 511 and 512 and allowing the reinforcement member 716 to fit there.

In the board part 71, the surface 711 is provided with a plurality of (only two are illustrated in FIG. 11) first recesses 711d which are recessed toward the surface 712 and into which the reinforcement member 716 may fit.

Reinforcement between the first circuit board 5 and the relay board 7 is made by the reinforcement member 716 inserted into the first recess 711d through the first fitting receiving portion 511b and fitted into the first fitting receiving portion 511b and the first recess 711d.

The second fitting receiving portion 611b according to Modification 2-5 is formed of a through hole penetrating between the plate surfaces 611 and 612 and allowing the reinforcement member 716 to fit there.

In the board part 71, the surface 712 is provided with a plurality of (only two are illustrated in FIG. 11) second recesses 712d which are recessed toward the surface 711 and into which the reinforcement member 716 may fit.

Reinforcement between the second circuit board 6 and the relay board 7 is made by the reinforcement member 716 inserted into the second recess 712d through the second fitting receiving portion 611b and fitted into the second fitting receiving portion 611b and the second recess 712d.

The first and second fitting receiving portions 511b and 611b and the first and second recesses 711d and 712d are not limited to the configuration in which they are provided in advance. They may be formed in the process of inserting the reinforcement member 716.

### Third Embodiment

Next, a third embodiment will be described.

Hereinafter, the same reference numerals are given to the same configurations as those of the above-described first embodiment, and the detailed description thereof will be omitted or simplified.

The electronic circuit board 4 according to the third embodiment is configured to perform high-speed transmission between the first and second circuit boards 5 and 6 via the relay board 7. That is, in the relay board 7 according to the third embodiment, a structure that enables high-speed transmission is employed as the transmission line 72.

### Structure of Transmission Line in Relay Board

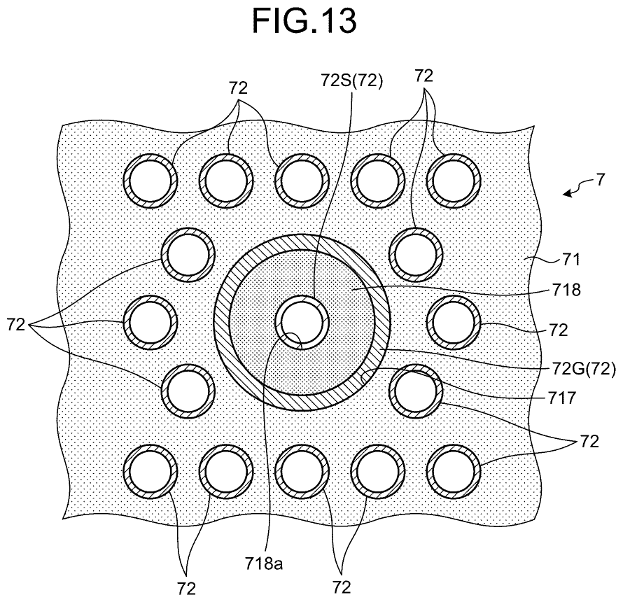

FIG. 13 is a diagram illustrating a structure of the transmission line 72 in the relay board 7 according to the third embodiment of the present disclosure. Specifically, FIG. 13 is a sectional view of the relay board 7 cut along a plane parallel to the plate surface 511.

The board part 71 is provided with an outer through hole 717 (FIG. 13) having a circular section and penetrating between the surfaces 711 and 712. The outer through hole 717 corresponds to a through hole according to the present disclosure.

The transmission line 72 that enables high-speed transmission includes the ground line 72G and a signal line 72S provided in the outer through hole 717.

As illustrated in FIG. 13, the ground line 72G is provided on the inner surface of the outer through hole 717 and constitutes a so-called through hole together with the outer through hole 717.

Here, the ground line 72G is filled with a filling member 718. The filling member 718 is formed of an insulator having a dielectric constant different from that of the board part 71. In the filling member 718, an inner through hole 718a having a circular section and penetrating between the surfaces 711 and 712 is provided in a portion positioned at the center of the outer through hole 717.

The signal line 72S is a transmission line that transmits a high-speed signal. As illustrated in FIG. 13, the signal line 72S is provided on the inner surface of the inner through hole 718a and constitutes a so-called through hole together with the inner through hole 718a.

In FIG. 13, the transmission line 72 provided outside the outer through hole 717 is a through hole used for purposes other than high-speed transmission.

As described above, in the third embodiment, a structure similar to a so-called coaxial cable is employed as the transmission line 72 that enables high-speed transmission. In the third embodiment, selecting a material having a specific dielectric constant different from that of the board part 71 as the material of the filling member 718 allows the characteristic impedance of the transmission line 72 that enables high-speed transmission to have a desired value (for example, 50 Ω.

### Effect of Third Embodiment

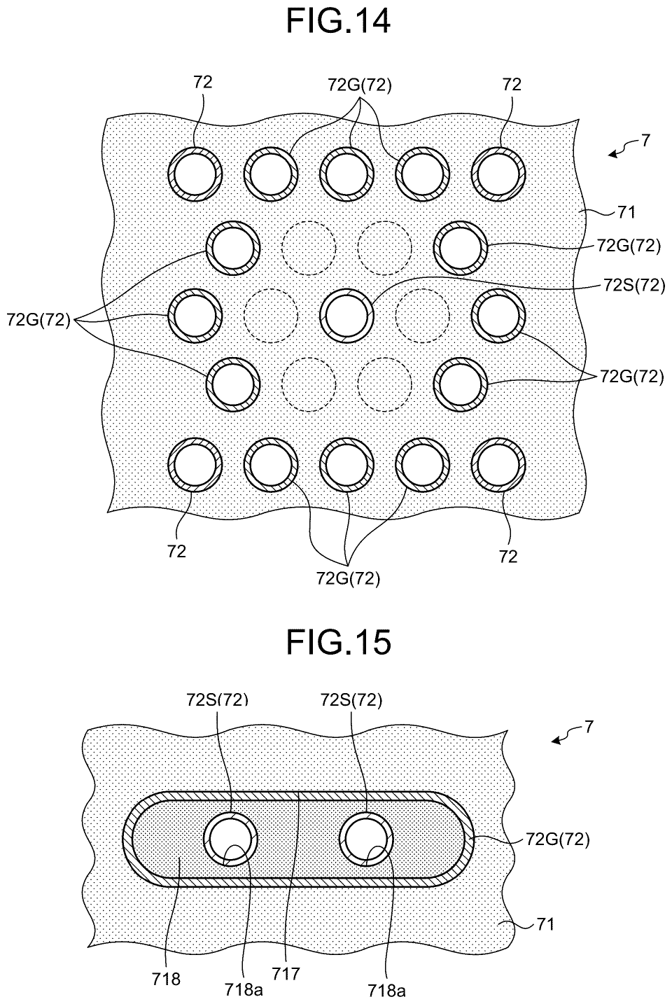

FIG. 14 is a diagram for explaining an effect of the third embodiment. Specifically, FIG. 14 is a sectional view corresponding to FIG. 13 illustrating another structure of the transmission line 72 that enables high-speed transmission different from the structure of the third embodiment.

As another structure of the transmission line 72 that enables high-speed transmission, the structure illustrated in FIG. 14 is conceivable.

Specifically, as illustrated in FIG. 14, a plurality of through holes are formed in the board part 71 in a closest-packing manner. The closest packing means an arrangement in which six through holes are disposed on the outer peripheral side of one through hole when the one through hole is focused among the plurality of through holes. Of the plurality of through holes, one through hole is defined as a signal line 72S, and 12 through holes forming a regular hexagonal shape surrounding the through hole as the signal line 72S are defined as ground lines 72G.

In FIG. 14, six circles with broken lines illustrated between the 12 through holes as the ground lines 72G and the one through hole as the signal line 72S are through holes that are not used or through holes that are not formed. The transmission line 72 provided outside the 12 through holes as the ground lines 72G is a through hole used for purposes other than high-speed transmission.

To set the characteristic impedance of the transmission line 72 that enables high-speed transmission to a desired value (for example, 50 Ω) in the structure illustrated in FIG. 14, it is necessary to separate the through holes as the ground lines 72G and the through hole as the signal line 72S by providing one through hole because of the influence of the dielectric constant of the board part 71. That is, as the transmission line 72 that enables high-speed transmission, an area for 19 through holes is required, and the area of the relay board 7 in the planar direction (in FIG. 14, a direction parallel to the paper surface) increases. For this reason, the area of the electronic circuit board 4 in the planar direction (in FIG. 1, a direction parallel to the paper surface) increases, which disturbs the downsizing. In addition, since there are gaps between the 12 through holes as the ground lines 72G, the radiation noise from the signal line 72S cannot be sufficiently confined.

In contrast, in the third embodiment, a structure similar to a so-called coaxial cable is employed as the transmission line 72 that enables high-speed transmission. In addition, the characteristic impedance of the transmission line 72 that enables high-speed transmission is set to have a desired value (for example, 50 Ω) by selecting a material having a specific dielectric constant different from that of the board part 71 as the material of the filling member 718.

Thus, the transmission line 72 that enables high-speed transmission has an area corresponding to seven through holes, and the area of the relay board 7 in the planar direction (in FIG. 13, a direction parallel to the paper surface) can be reduced. As a result, the area of the electronic circuit board 4 in the planar direction (in FIG. 1, a direction parallel to the paper surface) can be reduced, and downsizing can be achieved. In addition, since the ground line 72G is continuously formed to surround the signal line 72S, it is possible to sufficiently confine the radiation noise from the signal line 72S.

### Modification 3-1 of Third Embodiment

FIG. 15 is a diagram illustrating Modification 3-1 of the third embodiment. Specifically, FIG. 15 is a diagram corresponding to FIG. 13.

In the third embodiment described above, a differential transmission system may be employed as a system of the high-speed transmission. In such a case, as in Modification 3-1 illustrated in FIG. 15, through holes of two signal lines 72S for transmitting a differential signal (+) and a differential signal (−) forming a pair may be provided in the filling member 718. In FIG. 15, the outer through hole 717 has an elliptical sectional shape, but it may have another shape.

### Other Embodiments

The embodiments for carrying out the present disclosure have been described so far. The present disclosure should not be limited only by the first to third embodiments described above.

In the first to third embodiments described above, a smartphone has been exemplified as the electronic device according to the present disclosure, but the electronic device is not limited to a smartphone, and it may be configured as a camera, a headphone, an audio device, or a hearing aid.

In the first to third embodiments described above, the solder SO12 does not have to be connected to the relay board 7 as long as the first electronic component for reinforcement 531 is used as the reinforcement structure between the first circuit board 5 and the relay board 7. For example, when the solder SO12 is not connected to the relay board 7, the first electronic component for reinforcement 531 itself mounted on the first circuit board 5 abuts on the relay board 7, whereby reinforcement is made between the first circuit board 5 and the relay board 7. The same applies to the reinforcement structure between the second circuit board 6 and the relay board 7.

In the first to third embodiments described above, the first and second electronic components for reinforcement 531 and 631 are not limited to bypass capacitors, and other electronic components may be employed.

In the first to third embodiments described above, the solder SO12 is connected to the first circuit board 5 (plate surface 511) in addition to the ground line 72G, but the solder SO12 is not limited to this configuration, and it may be connected only to the ground line 72G. The same applies to the solder SO22.

In the first to third embodiments described above, the arrangement position of the first electronic component for reinforcement 531 is not limited to the inside of the frame of the relay board 7 as long as it is positioned at an internal corner portion between the first circuit board 5 and the relay board 7, and it may be arranged outside the frame.

The effects described in the present specification are merely illustrative or exemplary, and are not restrictive. That is, the technology according to the present disclosure can exhibit other effects obvious to those skilled in the art from the description of the present specification together with or instead of the above effects.

The following configurations also belong to the technical scope of the present disclosure.

(1)

An electronic circuit board including:
a first circuit board;
a second circuit board; and
a relay board sandwiched between the first circuit board and the second circuit board and electrically connecting the first circuit board and the second circuit board to each other,
wherein reinforcement between at least one of the first circuit board and the second circuit board and the relay board is made by using an electronic component for reinforcement provided at an internal corner portion between the at least one circuit board and the relay board among electronic components mounted on the at least one circuit board.
   (2)

The electronic circuit board according to (1), wherein
the electronic component for reinforcement is electrically connected to the at least one circuit board by solder, and
the solder connects between the at least one circuit board and the relay board at the internal corner portion.
   (3)

The electronic circuit board according to (1) or (2), wherein
a ground line is provided on a side surface of the relay board, and
the electronic component for reinforcement is connected to the ground line by solder to form ground connection.
   (4)

The electronic circuit board according to any one of (1) to (3), wherein
the electronic component for reinforcement includes:
a first electronic component for reinforcement provided at an internal corner portion between the relay board and the first circuit board; and
a second electronic component for reinforcement provided at an internal corner portion between the relay board and the second circuit board, wherein
reinforcement between the relay board and the first circuit board is made by using the first electronic component for reinforcement, and
reinforcement between the relay board and the second circuit board is made by using the second electronic component for reinforcement.
   (5)

The electronic circuit board according to any one of (1) to (4), wherein
one member of the at least one circuit board and the relay board is provided with a reinforcement member that protrudes toward the other member of the at least one circuit board and the relay board and is inserted into the other member.
   (6)

The electronic circuit board according to (5), wherein the reinforcement member is integrally formed with the one member.

(7)

The electronic circuit board according to (5), wherein
the reinforcement member is configured separately from the one member.
   (8)

The electronic circuit board according to any one of (1) to (7), wherein
the relay board includes:
a board part formed of an insulator and having a through hole penetrating from the first circuit board side toward the second circuit board side;
a ground line provided on an inner surface of the through hole;
a signal line provided to be separated from the ground line in the through hole; and
a filling member formed of an insulator and filled between the ground line and the signal line.
   (9)

The electronic circuit board according to (8), wherein
the board part and the filling member are different in dielectric constant.
   (10)

An electronic device including:
an exterior casing constituting an exterior;
an electronic circuit board housed in the exterior casing, wherein
the electronic circuit board includes:
a first circuit board;
a second circuit board; and
a relay board sandwiched between the first circuit board and the second circuit board and electrically connecting the first circuit board and the second circuit board to each other,
reinforcement between at least one of the first circuit board and the second circuit board and the relay board is made by using an electronic component for reinforcement provided at an internal corner portion between the at least one circuit board and the relay board among electronic components mounted on the at least one circuit board.

### REFERENCE SIGNS LIST

1 ELECTRONIC DEVICE

2 EXTERIOR CASING

3 DISPLAY UNIT

4 ELECTRONIC CIRCUIT BOARD

FIRST CIRCUIT BOARD

6 SECOND CIRCUIT BOARD

7 RELAY BOARD

51 FIRST BOARD PART

52 FIRST TRANSMISSION LINE

53 FIRST ELECTRONIC COMPONENT

61 SECOND BOARD PART

62 SECOND TRANSMISSION LINE

63 SECOND ELECTRONIC COMPONENT

71 BOARD PART

72 TRANSMISSION LINE

72G GROUND LINE

72S SIGNAL LINE

511, 512 PLATE SURFACE

511a FIRST PAD

511b FIRST FITTING RECEIVING PORTION

531 FIRST ELECTRONIC COMPONENT FOR REINFORCEMENT

611, 612 PLATE SURFACE

611a SECOND PAD

611b SECOND FITTING RECEIVING PORTION

631 SECOND ELECTRONIC COMPONENT FOR REINFORCEMENT

711, 712 SURFACE

711a FIRST LAND

711b PROTRUSION

711c FIRST SCREW HOLE

711d FIRST RECESS

712a SECOND LAND

712b PROTRUSION

712c SECOND SCREW HOLE

712d SECOND RECESS

713 THROUGH HOLE

714 to 716 REINFORCEMENT MEMBER

717 OUTER THROUGH HOLE

718 FILLING MEMBER

718a INNER THROUGH HOLE

I1, I2 INTERNAL CORNER PORTION

RE RESIN

SO, SO11, SO12, SO21, SO22 SOLDER

1. An electronic circuit board including:
a first circuit board;
a second circuit board; and
a relay board sandwiched between the first circuit board and the second circuit board and electrically connecting the first circuit board and the second circuit board to each other,
wherein reinforcement between at least one of the first circuit board and the second circuit board and the relay board is made by using an electronic component for reinforcement provided at an internal corner portion between the at least one circuit board and the relay board among electronic components mounted on the at least one circuit board.

2. The electronic circuit board according to claim 1, wherein
the electronic component for reinforcement is electrically connected to the at least one circuit board by solder, and
the solder connects between the at least one circuit board and the relay board at the internal corner portion.

3. The electronic circuit board according to claim 1, wherein
a ground line is provided on a side surface of the relay board, and
the electronic component for reinforcement is connected to the ground line by solder to form ground connection.

4. The electronic circuit board according to claim 1, wherein
the electronic component for reinforcement includes:
a first electronic component for reinforcement provided at an internal corner portion between the relay board and the first circuit board; and
a second electronic component for reinforcement provided at an internal corner portion between the relay board and the second circuit board, wherein
reinforcement between the relay board and the first circuit board is made by using the first electronic component for reinforcement, and
reinforcement between the relay board and the second circuit board is made by using the second electronic component for reinforcement.

5. The electronic circuit board according to claim 1, wherein
one member of the at least one circuit board and the relay board is provided with a reinforcement member that protrudes toward the other member of the at least one circuit board and the relay board and is inserted into the other member.

6. The electronic circuit board according to claim 5, wherein
the reinforcement member is integrally formed with the one member.

7. The electronic circuit board according to claim 5, wherein
the reinforcement member is configured separately from the one member.

8. The electronic circuit board according to claim 1, wherein
the relay board includes:
a board part formed of an insulator and having a through hole penetrating from the first circuit board side toward the second circuit board side;
a ground line provided on an inner surface of the through hole;
a signal line provided to be separated from the ground line in the through hole; and
a filling member formed of an insulator and filled between the ground line and the signal line.

9. The electronic circuit board according to claim 8, wherein
the board part and the filling member are different in dielectric constant.

10. An electronic device including:
an exterior casing constituting an exterior;
an electronic circuit board housed in the exterior casing, wherein
the electronic circuit board includes:
a first circuit board;
a second circuit board; and
a relay board sandwiched between the first circuit board and the second circuit board and electrically connecting the first circuit board and the second circuit board to each other,
reinforcement between at least one of the first circuit board and the second circuit board and the relay board is made by using an electronic component for reinforcement provided at an internal corner portion between the at least one circuit board and the relay board among electronic components mounted on the at least one circuit board.
